(19) United States
(12) Patent Application Publication
(10) Pub. No.: US 2024/0258074 A1
(43) Pub. Date: Aug. 1, 2024

(54) Antenna Plane Magnets for Improved Performance

(71) Applicant: Tokyo Electron Limited, Tokyo (JP)

(72) Inventors: Chelsea DuBose, Austin, TX (US); Barton Lane, Austin, TX (US); Justin Moses, Austin, TX (US); Merritt Funk, Austin, TX (US); Mitsunori Ohata, Taiwa-cho (JP)

(21) Appl. No.: 18/162,876

(22) Filed: Feb. 1, 2023

(51) Int. Cl. H01J 37/32

(52) U.S. Cl. CPC H01J 37/3222; H01J 2237/327

(57) ABSTRACT

According to an embodiment, a plasma processing system includes a plasma chamber, a planar antenna, a dielectric plate, and a plurality of magnets. The planar antenna is configured to generate plasma within the plasma chamber. The dielectric plate is disposed between the plasma chamber and the planar antenna. The magnets are arranged vertically above an outer surface of the dielectric plate that faces the plasma chamber.

### TECHNICAL FIELD

The present disclosure generally relates to semiconductor processing technology and, in particular embodiments, to magnets used in a plasma processing system.

### BACKGROUND

Plasma processing is extensively used in the manufacturing and fabrication of high-density microscopic circuits within the semiconductor industry. In a plasma processing system, an electromagnetic wave radiated into a plasma chamber generates an electromagnetic field. The generated electromagnetic field heats electrons in the chamber. The heated electrons ignite plasma that treats the substrate in a process such as etching, deposit, oxidation, sputtering, or the like.

Generally, during an operation of the plasma processing system, the impedance of the plasma within the plasma chamber varies considerably. For example, the plasma impedance variation can be due to the operating frequency, change in temperature and pressure within the plasma chamber, increased or decreased gas flow rates, and the like. A matching network is utilized to match the plasma chamber impedance to that of the transmission line. An automatic tuning algorithm typically controls the matching network quicker than a human could. Disadvantageously, existing tuning algorithms struggle to match at low or ultra-low pressures.

Moreover, plasma stability is problematic at low pressures (e.g., below 10 millitorr (mTorr)). Additionally, the density of the plasma is too low to be viable for processing semiconductor wafers at low and ultra-low pressures.

An apparatus and system that allows the operation of the plasma chamber at low and ultra-low pressure conditions are, thus, desirable.

### SUMMARY

Technical advantages are generally achieved by embodiments of this disclosure which describe magnets in a plasma processing system.

A first aspect relates to a plasma processing system. The plasma processing system includes a plasma chamber, a planar antenna, a dielectric plate, and a plurality of magnets. The planar antenna is configured to generate plasma within the plasma chamber. The dielectric plate is disposed between the plasma chamber and the planar antenna. The magnets are arranged vertically above the outer surface of the dielectric plate that faces the plasma chamber.

In a first implementation form of the plasma processing system according to the first aspect as such, one or more magnets of the plurality of magnets are a permanent magnet, an electromagnet, an electro-permanent magnet (EPM), or a combination thereof.

In a second implementation form of the plasma processing system according to the first aspect as such or any preceding implementation form of the first aspect, one or more magnets of the plurality of magnets have an axis of polarity perpendicular to the dielectric plate, parallel to the dielectric plate, or a combination thereof.

In a third implementation form of the plasma processing system according to the first aspect as such or any preceding implementation form of the first aspect, one or more magnets of the plurality of magnets are arranged along a ring parallel to the planar antenna. Further, one or more magnets of the plurality of magnets have an axis of polarity perpendicular to the ring, tangent to the ring, or a combination thereof.

In a fourth implementation form of the plasma processing system according to the first aspect as such or any preceding implementation form of the first aspect, the plasma processing system further includes a housing structure, the antenna arranged within the housing structure, and the dielectric plate positioned between the housing structure and the plasma chamber.

In a fifth implementation form of the plasma processing system according to the first aspect as such or any preceding implementation form of the first aspect, one or more magnets of the plurality of magnets are arranged external to the housing structure.

In a sixth implementation form of the plasma processing system according to the first aspect as such or any preceding implementation form of the first aspect, one or more magnets of the plurality of magnets are arranged on a plane parallel to the planar antenna.

In a seventh implementation form of the plasma processing system according to the first aspect as such or any preceding implementation form of the first aspect, the plane is adjustable in a vertical direction from the outer surface of the dielectric plate that faces the plasma chamber to a second plane. Further, the planar antenna is arranged between the second plane and the dielectric plate.

A second aspect relates to a plasma processing system. The plasma processing system includes a plasma chamber, an antenna, a dielectric plate, and a plurality of magnets. The plasma chamber has a top side and a bottom side opposing the top side. The antenna is configured to generate plasma in a plasma generating region within the plasma chamber. The dielectric plate is arranged between the plasma chamber and the antenna. Further, the uppermost surface of the plasma generating region is a surface corresponding to the bottom side of the dielectric plate adjacent to the top side of the plasma chamber. The magnets are arranged vertically above the uppermost surface of the plasma generating region in a direction from bottom side of the plasma chamber toward the top side of the plasma chamber. Moreover, a position or an axis of polarity of one or more of the magnets is configurable.

In a first implementation form of the plasma processing system according to the second aspect as such, one or more magnets of the plurality of magnets are a permanent magnet, an electromagnet, an electro-permanent magnet (EPM), or a combination thereof.

In a second implementation form of the plasma processing system according to the second aspect as such or any preceding implementation form of the second aspect, one or more magnets of the plurality of magnets have an axis of polarity perpendicular to the plasma, parallel to the plasma, or a combination thereof.

In a third implementation form of the plasma processing system according to the second aspect as such or any preceding implementation form of the second aspect, the antenna is in a shape of a donut. Further, a first subset of magnets is arranged on a first plane at an outer circumference of the antenna and parallel to the antenna. Moreover, a second subset of magnets is arranged on a second plane within an inner circumference of the antenna and parallel to the antenna. In embodiments, the first plane and the second plane are the same plane.

In a fourth implementation form of the plasma processing system according to the second aspect as such or any preceding implementation form of the second aspect, the magnets of the first subset of magnets are arranged symmetrically around the outer circumference of the antenna. Further, the magnets of the second subset of magnets are arranged symmetrically within the inner circumference of the antenna.

In a fifth implementation form of the plasma processing system according to the second aspect as such or any preceding implementation form of the second aspect, a determination of an arrangement of the magnets is based on a change in density, stability, pressure, ignition stability of the plasma, change in tunability of a matching network coupled to the antenna, or a combination thereof.

In a sixth implementation form of the plasma processing system according to the second aspect as such or any preceding implementation form of the second aspect, the plasma is a low-pressure plasma corresponding to a pressure of 10 millitorr (mTorr) or less.

A third aspect relates to a method of operating a plasma processing system. The plasma processing system includes a plasma chamber, an antenna, a dielectric plate, and a plurality of magnets. The antenna is used to generate plasma within the plasma chamber. The dielectric plate is arranged between the plasma chamber and the antenna. And, the magnets are arranged vertically above an outer surface of the dielectric plate that faces the plasma chamber.

The method includes setting a plasma processing operation for the plasma processing system, measuring one or more parameters associated with the plasma processing system, and adjusting a placement of one or more magnets based on the plasma processing operation and the one or more parameters.

In a first implementation form of the method according to the third aspect as such, the one or more parameters is one or more of plasma stability, electron temperature, plasma ignition stability, plasma density, or tunability of a matching network coupled to the antenna.

In a second implementation form of the method according to the third aspect as such or any preceding implementation form of the third aspect, one or more magnets of the plurality of magnets are stationary electromagnets. Further, adjusting the placement of one or more magnets includes enabling, disabling, adjusting, or reversing a current in one or more of the stationary electromagnets.

In a third implementation form of the method according to the third aspect as such or any preceding implementation form of the third aspect, one or more magnets of the plurality of magnets are permanent magnets arranged on a mechanical structure parallel to the outer surface of the dielectric plate. Further, adjusting the placement of one or more magnets comprises vertically shifting the mechanical structure between a first plane and a second plane. The first plane is the outer surface of the dielectric plate, and the second plane is a plane vertically above the antenna.

In a fourth implementation form of the method according to the third aspect as such or any preceding implementation form of the third aspect, the adjusting includes determining a configuration of magnets using a look-up table having a plurality of configurations for the magnets based on the plasma processing operation and the one or more parameters.

Embodiments can be implemented in hardware, software, or in any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a diagram of an embodiment plasma processing system;

FIG. 2A is a diagram of an embodiment plasma processing system with vertical plane placement options for various magnet configurations;

FIG. 2B is a top-down view of possible magnet placements on a plane;

FIG. 3 is a top-view diagram of an embodiment arrangement of magnets;

FIG. 4 is a top-view diagram of an embodiment arrangement of magnets;

FIG. 5 is a top-view diagram of an embodiment arrangement of magnets;

FIG. 6 is a top-view diagram of an embodiment arrangement of magnets;

FIG. 7 is a top-view diagram of an embodiment arrangement of magnets;

FIG. 8 is a block diagram of an embodiment processing system; and

FIG. 9 is a flow chart of an embodiment method for adjusting the magnet configuration of the plasma processing system.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise.

Variations or modifications described to one of the embodiments may also apply to other embodiments. Further, it should be understood that various changes, substitutions, and alterations can be made herein without departing from the spirit and scope of this disclosure as defined by the appended claims.

In an embodiment, the low pressure is equal to or less than 1 millitorr (mTorr). In an embodiment, the low-pressure condition is equal to or less than 10 mTorr.

While inventive aspects are described primarily in the context of a plasma chamber for treating substrates, the inventive aspects may be similarly applicable to fields outside the semiconductor industry. For example, plasma can be used to treat and modify surface properties through functional group addition, such as to treat surfaces for paint deposits by converting hydrophobic surfaces to hydrophilic surfaces. Regardless of the industry, having an apparatus that allows the reliable operation of a plasma chamber at low (and ultra-low pressure) plasma conditions is desirable.

In various embodiments, the arrangement of the various components and magnets are shown symmetrically to provide, for example, uniformity within the system. However, it should be appreciated that such symmetry is not required, and non-symmetrical arrangements may be purposefully introduced to correct, for example, non-uniformity within the system or to generate a skewed chamber effect.

Generally, a radiating antenna is used to radiate an RF wave, that generates an electromagnetic field within a plasma chamber, which ignites and sustains plasma within the plasma chamber. An impedance associated with the plasma generated in the plasma chamber corresponds to the load of the radiating antenna during its operation. The impedance of the plasma can vary based on, for example, changes in pressure, temperature, or operating conditions. Typically, a matching network (auto or manual) coupled to the radiating antenna is used to minimize losses (i.e., reflected power) in response to changes in the load condition.

Plasma generated at low pressure (i.e., low-pressure plasma) is used to, for example, etch semiconductor wafers or form thin films in the plasma chamber. Conventionally, the operation of the plasma chamber has suffered from a variety of issues associated with low-pressure plasma conditions.

For example, at low pressure, the stability of the plasma is decreased, the plasma density becomes too low to be process viable, and the plasma ignition becomes unreliable. Additionally, current algorithms and matching networks are not fully developed to respond to the load conditions presented at low-pressure conditions in existing plasma processing systems.

Embodiments of this disclosure provide a system and method that improves plasma stability, increases plasma density, enhances ignition stability, and boosts tuning compatibility (i.e., under pulsed and continuous wave (CW) conditions) of the matching network at low pressures; thus, extending the performance of existing systems into the very low plasma range.

In various embodiments, magnets are used to improve plasma density, plasma stability, plasma ignition stability, and matching network tuning compatibility at low pressures. The disclosure provides various configurations of magnet placements in reference to the plasma processing system. The magnets can be permanent magnets, electromagnets, electro-permanent magnets (EPM), or any combination thereof.

Generally, permanent magnets are more easily implemented within existing plasma processing systems. Permanent magnets can be placed within or around a plasma processing system with minimal redesign. Further, permanent magnets are cheaper and easier to control compared with electromagnets. Electromagnets, however, provide increased options for controlling the overall magnet configuration profile within the system. The polarity of an electromagnet can be easily selected, for example, by reversing the current through the electromagnet. Further, an electromagnet can be enabled or disabled, or the strength of the magnet can be adjusted by, for example, controlling the current through the electromagnet.

In embodiments, a plurality of magnets is placed above a plasma generating region of the plasma processing system. In embodiments, the uppermost boundary of the plasma generating region is at the boundary between the plasma chamber and a dielectric plate separating the plasma chamber from a housing, which includes the radiating antenna. In embodiments, the plurality of magnets is placed at a plane parallel to the radiating antenna and the dielectric plate.

The plurality of magnets is placed on a plane substantially the same as the dielectric plate, on a plane between the radiating antenna and the dielectric plate, on a plane substantially the same as the radiating antenna, on a plane above the radiating antenna and the dielectric plate but below the top surface of the housing, or on a plane above the radiating antenna, the dielectric plate, and the top surface of the housing. In each arrangement, the magnets are placed above the plasma generating region and the plasma chamber. In some embodiments, the magnets are placed outside of the housing. In some embodiments, the placement of the magnets is static. In some embodiments, the magnets can be moved from one plane to another or horizontally on the same plane using electrical or mechanical devices. In some embodiments, the magnets may be on more than one plane. In some embodiments, a subset of the magnets can be disabled while the remaining subset of magnets remains enabled. In some embodiments, some magnets are radially aligned with each other, while in other embodiments, the magnets are radially staggered. In some embodiments, the entirety of the magnets may be on a single plane.

In some embodiments, the magnets have an axis of polarity that is perpendicular with the top of the plasma chamber. In some embodiments, the magnets have an axis of polarity that is parallel to the top of the plasma chamber. In some embodiments, the magnets are arranged in a ring pattern. In some embodiments, the magnets can have a polarity that is either perpendicular or tangent to the ring. In embodiments, multiple subsets of magnets are arranged in different configurations. In some embodiments, the magnets have an off-axis orientation (e.g., angled) to, for example, guide the bulk plasma.

The magnets may be arranged around an outer circumference, an inner circumference, at a center, in a concentric circle, or a combination thereof, in reference to the radiating antenna. These and further details are discussed in greater detail below.

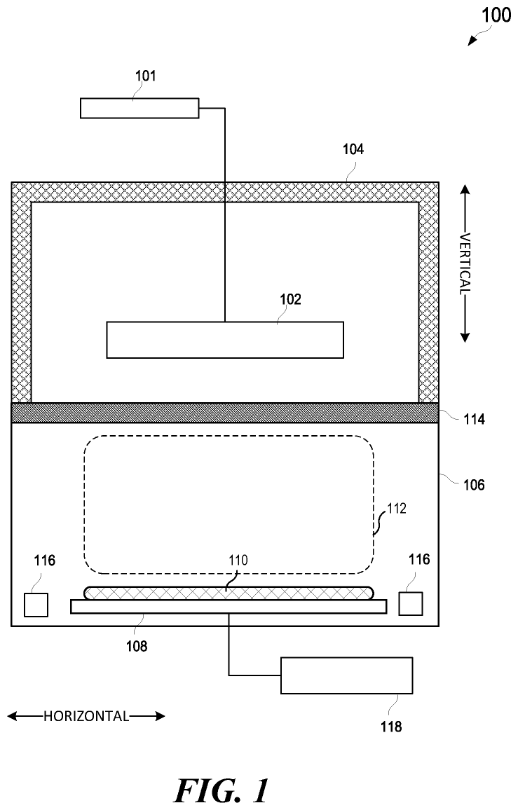

FIG. 1 illustrates a diagram of an embodiment plasma processing system 100. Plasma processing system 100 includes an antenna 102, a housing structure 104, a plasma chamber 106, and, optionally, a dielectric plate 114, which may (or may not) be arranged as shown in FIG. 1. Further, plasma processing system 100 may include additional components not depicted in FIG. 1.

In embodiments, antenna 102 is coupled to an RF source 101. RF source 101 includes an RF power supply, which may include a generator circuit and a matching circuit (not shown). RF source 101 is coupled to antenna 102 via a power transmission line, such as a coaxial cable or the like. RF source 101 provides forward RF waves to antenna 102, which are radiated towards plasma chamber 106.

In embodiments, plasma chamber 106 includes a substrate holder 108. As shown, substrate 110 is placed on substrate holder 108 to be processed. Optionally, plasma chamber 106 may include a bias power supply 118 coupled to substrate holder 108. The plasma chamber 106 may also include one or more pump outlets 116 to remove by-products from plasma chamber 106 through selective control of gas flow rates within. In embodiments, pump outlets 116 are placed near (e.g., below/around the perimeter of) substrate holder 108 and substrate 110. In embodiments, plasma chamber 106 may include additional substrate holders (not shown). In embodiments, the placement of the substrate holder 108 may differ from that shown in FIG. 1. Thus, the quantity and position of the substrate holder 108 are non-limiting.

In embodiments, antenna 102 radiates an electromagnetic field toward the plasma chamber 106. The radiated electromagnetic field generates an azimuthally symmetric, high-density plasma within a plasma generating region 112 with low capacitively coupled electric fields.

In embodiments, antenna 102 is a planar antenna as disclosed, for example, in further detail in U.S. application Ser. No. 17/664,607, U.S. application Ser. No. 17/649,823, U.S. application Ser. No. 17/748,737, U.S. application Ser. No. 17/985,360, and U.S. application Ser. No. 18/146,253, which are hereby incorporated herein by reference in their entirety.

In embodiments, antenna 102 is an inductively coupled antenna, such as a planar coil wound in a flat helix (i.e. stovetop antenna.)

For illustration purposes, the antenna 102, in embodiments, can be envisioned as a donut-shaped structure.

In an embodiment, antenna 102 includes arms connected to capacitive structures that generate the azimuthal symmetry. In embodiments, the excitation frequency of the antenna 102 is in the radio frequency range (10-400 MHz), which is not limiting, and other frequency ranges can similarly be contemplated. For example, inventive aspects disclosed herein equally apply to applications in the microwave frequency range.

In embodiments, antenna 102 includes resonant elements. The resonant elements can be arms that are electrically connected to capacitive structures. The arms and the capacitive structures are resonant with electromagnetic waves fed from the RF source 101.

In embodiments, resonant elements sustain standing electromagnetic waves. The resonant elements are placed close to and parallel to the dielectric plate 114 such that the oscillating magnetic field from the resonant elements penetrates the plasma chamber 106. The time-varying magnetic field induces a time-varying electric field, which transfers energy to plasma electrons.

In embodiments, the RF source 101 couples energy to an interface of the antenna 102 to generate the standing electromagnetic waves from the antenna 102. The RF source 101 is coupled to the interface via a transmission line in embodiments. It is desirable that the interface maintain the same or higher symmetry as the elements of antenna 102 under rotation about the axis of symmetry.

Additionally shown is housing structure 104, which surrounds antenna 102. Housing structure 104 is a conductive structure, which is electrically coupled to the RF ground of RF source 101 and, thus, RF grounded. In embodiments, housing structure 104 includes an opening to couple an RF feed path from RF source 101 to antenna 102.

In embodiments, housing structure 104 is positioned adjacent to the top of the plasma chamber 106, such that dielectric plate 114 is sandwiched between housing structure 104 and plasma chamber 106. The antenna 102, thus, generates electromagnetic waves that radiate through the dielectric plate 114 toward the plasma chamber 106.

In embodiments, antenna 102 is separated from plasma chamber 106 by the dielectric plate 114, which is typically made of a dielectric material. Dielectric plate 114 separates the low-pressure environment within plasma chamber 106 from the external atmosphere. It should be appreciated that antenna 102 can be placed directly adjacent to dielectric plate 114. In embodiments, antenna 102 is separated from plasma chamber 106 by air. In embodiments, the properties of the dielectric plate 114 are selected to minimize reflections of the RF wave from the plasma chamber 106. In other embodiments, antenna 102 is embedded within the dielectric plate 114. In embodiments, dielectric plate 114 is in the shape of a disk.

The dielectric plate 114 includes a first outer surface and a second outer surface. The first outer surface faces the plasma chamber 106. The second outer surface faces the antenna 102. The second outer surface is above the first outer surface in a vertical direction.

In an embodiment, the antenna 102 couples RF power from RF source 101 to the plasma chamber 106 to treat substrate 110. In particular, antenna 102 radiates an electromagnetic wave in response to being fed the forward RF waves from RF source 101. The radiated electromagnetic wave penetrates from the atmospheric side (i.e., antenna 102 side) of the dielectric plate 114 into plasma chamber 106. The radiated electromagnetic wave generates an electromagnetic field within the plasma chamber 106. The generated electromagnetic field ignites and sustains plasma in a plasma generating region 112 by transferring energy to free electrons within the plasma chamber 106. The generated plasma can be used to, for example, selectively etch or deposit material on substrate 110.

In embodiments, the plasma generating region 112 is immediately below the nearest portion of the dielectric plate 114 to the plasma chamber 106. In embodiments, the upper most surface of the plasma generating region 112 corresponds to the plane where the outer surface of the dielectric plate 114 faces the plasma chamber 106.

In FIG. 1, antenna 102 is external to plasma chamber 106. In embodiments, however, antenna 102 can be placed internal to the plasma chamber 106. In such an embodiment, the plasma generating region 112 is immediately below the nearest portion of the antenna 102 to the plasma chamber 106.

As disclosed herein and further detailed below, the plasma generating region 112 is used as a reference point for the positional arrangement of magnets.

In embodiments, the operating frequency of antenna 102 is between 5 and 100 megahertz (MHz). In embodiments, the power delivered by antenna 102 ranges from 10 to 5000 Watts (W)—determined by various factors such as distance from the antenna 102, impedance values, or the like.

As used herein, a “vertical direction” in reference to the plasma processing system refers to a direction from the housing structure 104 to the plasma chamber 106 through the dielectric plate 114. The terms “above” and “below,” in reference to the plasma processing system, are defined in the same context. For example, the plasma chamber 106 is below the dielectric plate 114, the antenna 102, and the housing structure 104; the dielectric plate 114 is below the antenna 102 and the housing structure 104 but above the plasma chamber 106; the antenna 102 is above the dielectric plate 114 and the plasma chamber 106 but below the top surface of the housing structure 104; and the housing structure 104 has a top surface that is above the plasma chamber 106, the dielectric plate 114, and the antenna 102.

As used herein, a “horizontal direction” in reference to the plasma processing system refers to a direction perpendicular to the vertical direction and along the housing structure 104 or the plasma chamber 106 from a first vertical sidewall to a second vertical sidewall of either structure.

The use of these terms is for increased clarity and does not place structural limitations on the embodiments of the disclosure.

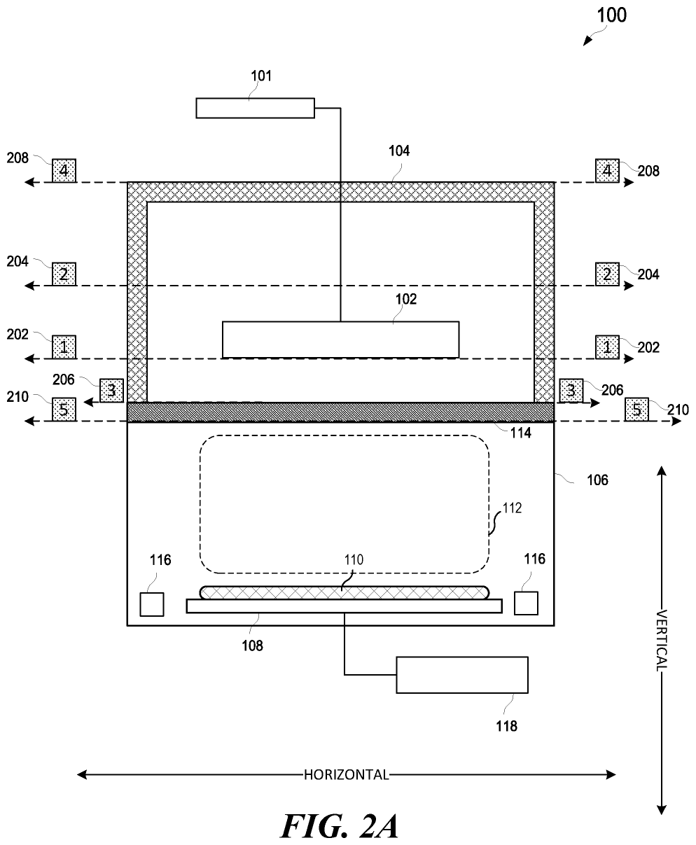

FIG. 2A illustrates a diagram of an embodiment plasma processing system 100 with vertical plane placement options 202-210 for various magnet configurations. In all magnet configurations, the magnets are placed above the plasma generating region 112. In embodiments, the plasma generating region 112 is immediately below the nearest portion of the dielectric plate 114 to the plasma chamber 106. In embodiments, the uppermost boundary of the plasma generating region 112 is at the boundary between the plasma chamber 106 and the dielectric plate 114 separating the plasma chamber 106 from the housing structure 104.

Placing the magnets above the plasma region improves plasma generation without greatly affecting the plasma energy distribution at the substrate. Magnets positioned around the plasma region can, for example, cause an undesired etch profile slant on portions of the wafer. Magnets can also be placed at a vertical distance from the plasma where the fields do not impact plasma density or uniformity but still improve ignition. In electromagnet embodiments, the magnets can be enabled only for ignition and then turned off.

In embodiments, magnets are placed at one or more placement options 202-210 to improve plasma density, plasma ignition stability, increase azimuthal uniformity, enhance the radial density profile of the plasma, and the like.

In embodiments, each magnet is arranged above an outer surface of the dielectric plate 114 that faces the plasma chamber 106. Each magnet is arranged vertically above the outer surface of the dielectric plate 114 along a direction from the plasma chamber 106 towards the antenna 102. In embodiments, magnets are arranged horizontally within the same vertical plane. These horizontal positions can be within or outside of the housing 104.

In embodiments, the region below the outer surface of the dielectric plate 114 along a direction from the dielectric plate 114 to the substrate holder 108 is defined herein as the plasma generating region.

In embodiments, antenna 102 is substantially parallel (i.e., less than 5% skew) with the dielectric plate 114, the substrate holder 108, and the substrate 110. In such embodiments, the plasma generated within plasma chamber 106 can be symmetric and uniform.

In embodiments, the magnets are placed on a plane identified as one of the placement options 202-210. In any of these embodiments, a plane associated with a set of magnets is defined as the plane positioned at the bottommost portion of the magnets (i.e., side nearest to the dielectric plate 114 and plasma chamber 106) and parallel with the dielectric plate 114.

The one or more magnets placed, or enabled (e.g., in an electromagnet case), at one or more placement options 202-210, induce a magnetic field within the plasma chamber. In embodiments, the magnetic field strength can be varied by changing the distance between the magnets and the plasma, enabling or disabling a subset of the magnets (e.g., in an electro-permanent magnet case), or adjusting the current flow in the electromagnet cases.

In embodiments, the magnetic field is a direct current (DC) magnetic field. In other embodiments, the magnetic field is oscillating. In embodiments, the magnetic field is pulsed. In embodiments, the magnetic field is permanent (e.g., when the magnets are permanent magnets). In embodiments, the magnetic field can be disabled (e.g., when the magnets are electromagnets).

The plane of the antenna 102 is defined as a plane positioned at the bottommost portion of antenna 102 (i.e., the side nearest to the dielectric plate 114) and parallel with the dielectric plate 114.

The plane of the dielectric plate 114 is defined as the bottom surface of dielectric plate 114 (i.e., the surface at the plasma interface).

The first placement option 202 of magnets is defined as on a plane substantially the same as the plane of the antenna 102. The vertical distance from the bottom of a magnet, when placed on a plane corresponding with the first placement option 202 and parallel with dielectric plate 114, to dielectric plate 114 is the same as the vertical distance from the bottom of antenna 102 to dielectric plate 114.

The second placement option 204 of magnets is defined as on a plane above the plane of the antenna 102 but below the top side (i.e., the side furthest to dielectric plate 114) of housing structure 104. The vertical distance to the dielectric plate 114 from the bottom of a magnet, when placed on a plane corresponding with the second placement option 204 and parallel with dielectric plate 114, is greater than the vertical distance to the dielectric plate 114 from the bottom of antenna 102 but less than the distance from the top side of housing structure 104 to dielectric plate 114.

The third placement option 206 of magnets is defined as on a plane below the plane of the antenna 102 but above dielectric plate 114. The vertical distance to the dielectric plate 114 from the bottom of a magnet, when placed on a plane corresponding with the third placement option 206 and parallel with dielectric plate 114, is less than the vertical distance to the dielectric plate from the bottom of antenna 102.

The fourth placement option 208 of magnets is defined as on a plane above the top side (i.e., the side furthest to dielectric plate 114) of housing structure 104. The vertical distance from a magnet, when placed on a plane corresponding with the fourth placement option 208 and parallel with dielectric plate 114, to dielectric plate 114 is greater than the vertical distance from the top side of housing structure 104 to dielectric plate 114.

The fifth placement option 210 of magnets is defined as a plane substantially the same as either surface of the dielectric plate 114 or between the two surfaces of the dielectric plate.

In each placement option 202-210, the magnets are placed at (i.e., corresponding to fifth placement option 210) or above dielectric plate 114. In embodiments, one or more magnets are placed in any of the vertical positions 202-210 and within housing structure 104. In embodiments, one or more magnets are placed in any of the vertical positions 202-210 and external housing structure 104. In embodiments, one or more magnets are placed within housing structure 104, in any of the vertical positions 202-210 while one or more magnets are placed external to housing structure 104, in any of the vertical positions 202-210.

In an embodiment, all magnets are placed only on a single plane identified as one of the identified placement options 202-210. In another embodiment, magnets are placed on a plane identified as one of the identified placement options 202-210. In some embodiments, at least one magnet is placed on a plane identified as one of the identified placement options 202-210.

Embodiments of this disclosure provide a plasma processing system 100 having magnets on a plane parallel to antenna 102, but not necessarily on the same plane as antenna 102.

In an embodiment, the magnets, in their entirety, can be moved mechanically or electronically from one placement option to another placement option (i.e., vertically). In an embodiment, the magnets, in their entirety, can be moved mechanically or electronically across a plane corresponding to one of the identified placement options 202-210 (i.e., horizontally). For example, the magnets may be on one or more structures or mounted on one or more structures that can manually or automatically move from one placement option to another in a vertical direction or across a plane.

In an embodiment, electromagnets or electro-permanent magnets are placed at the identified placement options 202-210. In such an embodiment, a subset or all magnets may be enabled or disabled on one or more of the identified placement options. Thus, in a first configuration, only the electromagnets or electro-permanent magnets located at the first placement option 202 are enabled; in a second configuration, only the electromagnets or electro-permanent magnets located at the second placement option 204 are enabled, and so on. In some embodiments, electromagnets or electro-permanent magnets are enabled in more than one placement option 202-210 simultaneously.

In an embodiment, one or more permanent magnets are placed at one or more of the placement options 202-210 in an asymmetric (e.g., misaligned along a vertical center point) manner to correct for a plasma asymmetry generated, for example, by the antenna or plasma chamber.

In an embodiment, one or more electromagnets or electro-permanent magnets are enabled at one or more of the placement options 202-210 in a non-symmetric (e.g., misaligned along a vertical center point) manner to correct for a plasma asymmetry generated, for example, by the antenna or plasma chamber.

In an embodiment, permanent magnets are placed at one or more of the placement options 202-210 in a symmetric (e.g., aligned along a vertical center point) manner to avoid a plasma asymmetry generated, for example, by the antenna or plasma chamber.

In an embodiment, electromagnets or electro-permanent magnets are enabled at one or more of the placement options 202-210 in a symmetric (e.g., aligned along a vertical center point) manner to avoid a plasma profile slant, for example, during an etch procedure.

The determination of the placement, quantity, and strength of the magnets varies based on the operational configuration of the plasma processing system.

For example, one factor considered may be the difference between the Larmor radius to the scale length of the plasma chamber 106 given the magnetic flux density of the generated magnetic field.

A charged particle (e.g., an electron) in a magnetic field travels in a spiral or helical motion (i.e., gyrates) along a direction parallel to the magnetic field. The transverse radius of the helical orbit that the charged particle traverses is referred to as the Larmor radius. The Larmor radius of an electron is proportional to the inverse of the magnetic flux density of the magnetic field.

In embodiments, the Larmor radius is preferably small compared to the scale length of the plasma chamber 106. For example, where the magnetic flux density is 1 gauss, the Larmor radius is relatively large and comparable to the size of the plasma chamber 106. So, in this example, the effect of the magnetic field on the charged particle within the plasma chamber 106 is small.

In contrast, where the magnetic flux density is, for example, 10 gauss, the Larmor radius is magnitudes smaller. In this example, the charged particles are more isolated to field lines, and the effect of the magnetic field is, therefore, stronger.

However, as the magnetic field increases, there is a limitation to a change in the behavior of the plasma within the plasma chamber 106. Thus, there is a point where an increase in the magnetic field provides a negligible impact.

As another example, another factor that can be taken into consideration may be the magnetic field strength. The frequency of rotation of electrons in a magnetic field depends linearly on the magnetic field strength. For example, by doubling the magnetic field strength, one can double the rate of rotation of the electrons. Further, if the frequency of the RF field is in sync (i.e., coincides) with the rate of rotation, the energy transfer from the RF field to the electron is enhanced (i.e., electron cyclotron resonance).

Other factors that are considered in selecting the placement, quantity, and strength of the magnets are, for example, the type of antenna 102, the plasma chemistry in the plasma chamber 106, the type of operation being undertaken within the plasma chamber 106, or the like.

In a first embodiment, N number of magnets are placed at one or more of the placement options 202-210. In a second embodiment, M number of magnets are placed at one or more of the placement options 202-210 to achieve the same overall result, where M is greater than N, and the strength of magnets in the first embodiment is greater than the strength of magnets in the second embodiment.

The plasma processing systems 100 in FIGS. 1 and 2 are shown as symmetric structures—with components that are arranged parallel to each other and have a center point, which is aligned on a straight line. It should be appreciated, however, that a non-symmetric plasma processing system may also take advantage of magnets as disclosed herein.

In an embodiment where the magnets are electromagnets or electro-permanent magnets, the electromagnets or electro-permanent magnets may be enabled during the plasma processing and disabled when the plasma processing step has been completed.

FIG. 2B illustrates a top-down view (i.e., vertical and in a direction looking down from the antenna 102 to plasma chamber 106) of a possible (i.e., not limited to the magnet positions shown in FIG. 2B) magnet 242 placements on a plane corresponding to any of the 202-210 in FIG. 2A.

In FIG. 2B, housing structure 104 is shown to have a cylindrical structure (i.e., with a circular cross-section); however, other geometric shapes for housing structure 104 are contemplated.

A magnet 242 can be placed at any position on the plane defined by any of the 202-210 (with the obvious caveat that two bodies cannot occupy the same space). For example, a magnet 242 may be positioned within an example outline 244 of antenna 102 where antenna 102 is a structure having an open volume (i.e., not a solid cylinder) on the plane. A magnet may be placed on the plane interior or exterior to housing structure 104.

Although no particular uniformity or pattern in the placement of magnets is shown in FIG. 2B, embodiments where the magnets are, for example, uniformly arranged in a particular pattern, such as symmetrically positioned, or arranged concentric to, for example, a center point of the antenna 102 is also contemplated. For example, magnets can be arranged in a ring outline arranged concentric to antenna 102 (e.g., having the same center point as antenna 102).

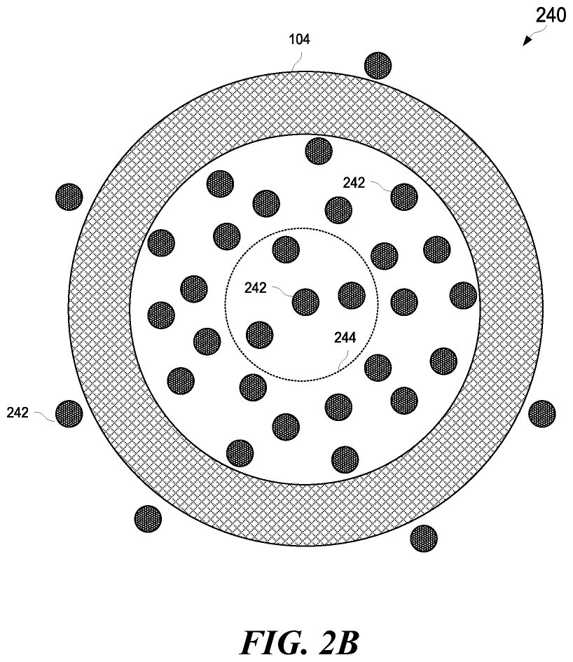

A magnet 242 or a subset of magnets can be arranged to have a particular axis of polarity (e.g., embodiments in FIGS. 3, 4, and 5). In embodiments, the position and axis of polarity of each magnet 242 are configurable. For example, the position of each magnet 242 may be mechanically or electronically adjusted in a vertical or horizontal direction based on, for example, measurements on sampled wafers or based on a feedback circuit that measures one or more properties of the plasma. As another example, the axis of polarity of a magnet 242 may be mechanically or electronically adjusted using similar methods as that used to adjust the vertical and horizontal positioning of a magnet 242. In embodiments, the magnet 242 is an electromagnet or an electro-permanent magnet. In such an embodiment, instead of vertically and horizontally adjusting the position of the magnet 242, a magnet 242 may be enabled on different planes or different horizontal positions on the same plane while other magnets are disabled on the same plane (i.e., horizontal adjustment) or on a different plane (i.e., vertical adjustment).

Thus, it should be understood that although in embodiments, a particular vertical and horizontal positioning of a magnet 242 and an associated axis of polarity may be desirable, a magnet 242 may be arranged in any location (horizontally and vertically) above the plasma generating region (i.e., away from plasma chamber 106 and toward antenna 102) with any variety in the axis of polarity.

FIG. 3 illustrates a top-view (i.e., vertical and in a direction looking down from the antenna 102 to the plasma chamber 106) diagram of an embodiment arrangement of magnets 300 that may be used in any placement options 202-210, as shown in FIG. 2A.

Magnets 302 are located on a plane in a ring-shaped arrangement, which is parallel to the plane of the dielectric plate 114. As shown, magnets 302 are situated along the ring such that the axis of polarity of each magnet 302 is perpendicular to the plasma within the plasma chamber 106 (i.e., axis of polarity on the vertical plane). The polarity of each magnet is also perpendicular to the outline of the ring shape.

In embodiments, the magnets 302 are cylindrical magnets with axial polarity. In embodiments, the axial polarity of the magnets can be reversed either manually, for example, in the case of a permanent magnet, or electrically, for example, in the case of an electromagnet by reversing the current.

Each magnet 302 is illustrated with having a north pole that is further away from the plasma chamber 106 than its respective south pole. However, this arrangement is non-limiting and for illustrative purposes only. For example, in an embodiment, magnets 302 may be arranged in a configuration such that the south pole of each magnet 302 is further away from the plasma chamber 106 than the north pole of each magnet 302. As another example, in embodiments, some magnets 302 are arranged such that their north pole is further away than their south pole with respect to the plasma chamber 106, while other magnets 302 on the same ring are arranged such that their south pole is further away than their north pole with respect to the plasma chamber 106. In some embodiments, these arrangements are symmetric, while in others, the arrangements are non-symmetric.

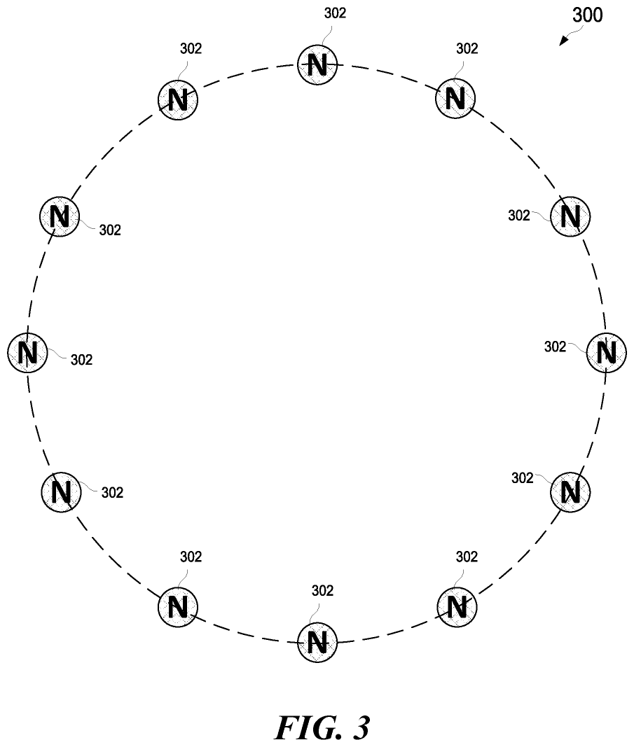

FIG. 4 illustrates a top-view (i.e., vertical and in a direction looking down from the antenna 102 to the plasma chamber 106) diagram of an embodiment arrangement of magnets 400 that may be used in any placement options 202-210, as shown in FIG. 2A.

Magnets 402 are located on a plane in a ring-shaped arrangement, which is parallel to the plane of the dielectric plate 114. As shown, magnets 402 are situated along the ring such that the axis of polarity of each magnet 402 is parallel to the plasma within the plasma chamber 106 (i.e., axis of polarity on the horizontal plane) and tangent to the outline of the ring.

Each magnet 402 is illustrated with having a north pole that is further counterclockwise along the ring with respect to its south pole. However, this arrangement is non-limiting and for illustrative purposes only. For example, in an embodiment, each magnet 402 may be arranged in a configuration such that its south pole is further counterclockwise along the ring with respect to its north pole. As another example, in embodiments, some magnets 402 are arranged such that their respective north poles are further counterclockwise along the ring with respect to their south pole, while other magnets 402 on the same ring are arranged such that their respective south poles are further counterclockwise along the ring with respect to their north pole. In some embodiments, these arrangements are symmetric, while in others, the arrangements are non-symmetric.

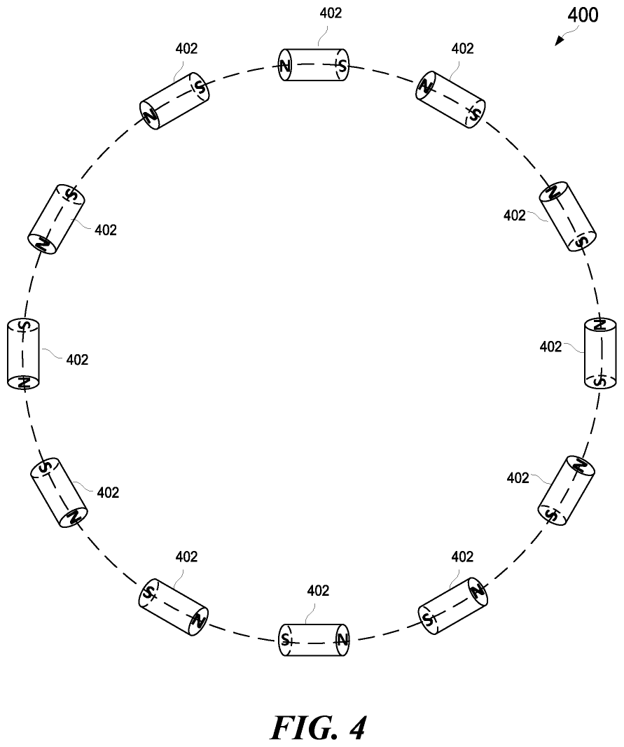

FIG. 5 illustrates a top-view (i.e., vertical and in a direction looking down from the antenna 102 to the plasma chamber 106) diagram of an embodiment arrangement of magnets 500 that may be used in any placement options 202-210, as shown in FIG. 2A.

Magnets 502 are located on a plane in a ring-shaped arrangement on a plane, which is parallel to the plane of the dielectric plate 114. As shown, magnets 402 are situated along the ring such that the axis of polarity of each magnet 402 is parallel to the plasma within the plasma chamber 106 (i.e., axis of polarity on the horizontal plane) and perpendicular to the outline of the ring.

Each magnet 502 is shown to have north and south poles along a line connected through the center of the ring, with its respective north pole being nearer along the line to the center of the ring than its south pole. However, this arrangement is non-limiting and for illustrative purposes only. For example, in an embodiment, the respective south pole of each magnet is nearer along the line to the center of the ring than its north pole. As another example, in embodiments, some magnets 502 are arranged such their respective north poles are nearer along the line to the center of the ring than their south pole, while other magnets 502 are arranged such that their respective south poles are nearer along the line to the center of the ring than their north pole. In some embodiments, these arrangements are symmetric, while in others, the arrangements are non-symmetric.

The dashed-line ring outlines shown in FIGS. 3, 4, and 5 can be positioned on any of the planes shown in FIG. 2A. The rings can have diameters larger, smaller, or substantially the same as the antenna 102.

In an embodiment (not shown), antenna 102 has arms connecting an inner ring with an outer ring in a manner resembling the spokes of a wagon wheel. In such an embodiment, magnets are placed within a gap between the arms; thus, on the same plane as the planar antenna and between the inner circumference and the outer circumference of antenna 102. In some embodiments, the magnets are on the same plane, below, or above antenna 102.

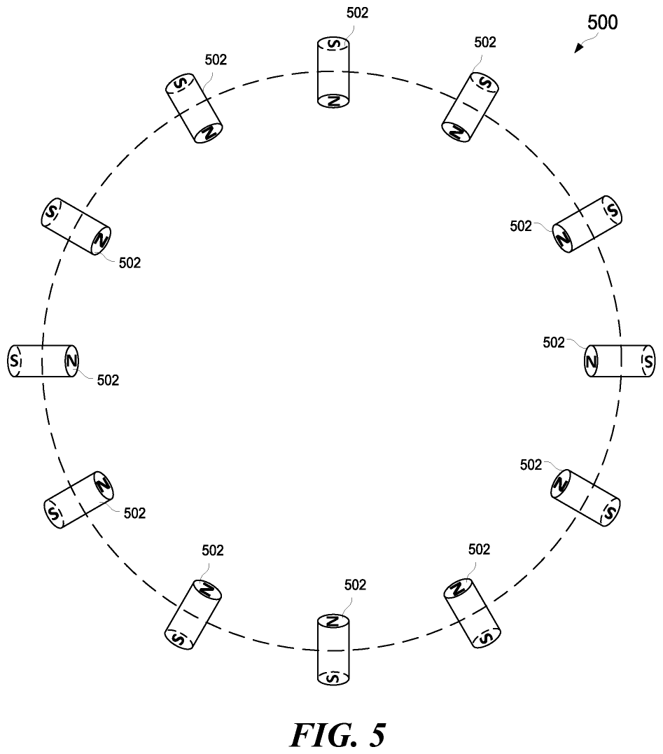

FIG. 6 illustrates a top-view (i.e., vertical and in a direction looking down from the antenna 102 to the plasma chamber 106) diagram of an embodiment arrangement of magnets 600 that may be used in any placement options 202-210, as shown in FIG. 2A. Magnets 602 and 604 correspond to one or more of the magnets as disclosed with respect to the arrangement of magnets 300, arrangement of magnets 400, arrangement of magnets 500, or a combination thereof.

In the arrangement of magnets 600, the first set of magnets 602 is arranged at an outer circumference of antenna 102, and the second set of magnets 604 is arranged at an inner circumference of antenna 102. The magnets 602 and 604 in FIG. 6 are shown to be radially aligned. The centers of the rings corresponding to the first set of magnets 602 and the second set of magnets 604 are the same as the center of the, for example, donut-shaped antenna 102.

It is noted that the first set of magnets 602 and the second set of magnets 604 are not required to be on the same vertical plane as antenna 102 or the same plane as each other. The first set of magnets 602 and the second set of magnets 604, for example, may be arranged vertically above or below antenna 102.

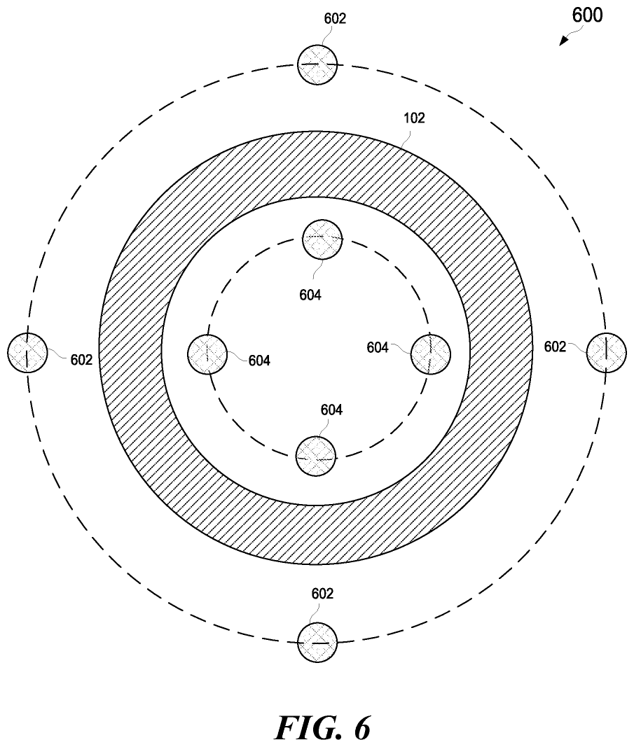

FIG. 7 illustrates a top-view (i.e., vertical and in a direction looking down from the antenna 102 to the plasma chamber 106) diagram of an embodiment arrangement of magnets 700 that may be used in any placement options 202-210, as shown in FIG. 2A. Magnets 702 and 704 correspond to one or more of the magnets as disclosed with respect to the arrangement of magnets 300, arrangement of magnets 400, arrangement of magnets 500, or a combination thereof.

In the arrangement of magnets 700, the first set of magnets 702 is arranged at an outer circumference of antenna 102, and the second set of magnets 704 is arranged at an inner circumference of antenna 102. The magnets 702 and 704 in FIG. 7 are shown to be radially staggered. The centers of the ring corresponding to the first set of magnets 702 and the second set of magnets 704 are the same as the center of the donut-shaped antenna 102.

It is noted that the first set of magnets 702 and the second set of magnets 704 are not required to be on the same vertical plane as antenna 102 or on the same plane as each other. The first set of magnets 702 and the second set of magnets 704, for example, may be arranged vertically above or below antenna 102.

In embodiments, a single permanent magnet may be envisioned in the shape of a ring, having one solid, constant magnetic field. In an embodiment, a single permanent magnet in the shape of a ring may replace magnets 302, 402, 502, 602, 604, 702, or 706. In another embodiment, a single electromagnet or electro-permanent magnet in the shape of a ring may replace the magnets 302, 402, 502, 602, 604, 702, or 706.

In embodiments, instead of having multiple individual magnets arranged along a ring, a singular electromagnet or electro-permanent magnet in the shape of the ring is contemplated. In this embodiment, the polarity of the ring-shaped electromagnet or electro-permanent magnet may be selectively changed, for example, by changing the winding(s) or reversing the current through the winding(s) to produce different-shaped magnetic fields or reversing the magnetic fields.

In embodiments, each magnet 302, 402, 502, 602, 604, 702, or 704 is a permanent magnet. In other embodiments, each magnet 302, 402, 502, 602, 604, 702, or 704 is an electromagnet or an electro-permanent magnet. In such an embodiment, the polarity of the electromagnet or electro-permanent magnet can be controlled, for example, by reversing or changing the current used to generate the magnetic effect.

In embodiments, some magnets 302, 402, 502, 602, 604, 702, or 704 are permanent magnets, while other magnets 302, 402, 502, 602, 604, 702, or 704 on the same ring are electromagnets or electro-permanent magnets.

In an embodiment, a single magnet 302, 402, or 502 is vertically positioned at the center of antenna 102. It is noted that the single magnet 302, 402, or 502, is not required to be on the same vertical plane as antenna 102. For example, the single magnet 302, 402, or 502 is arranged vertically above or below antenna 102.

Magnets in FIGS. 3-7 may be arranged in any location on the dashed ring line. Further, the magnets are not necessarily positioned at every position along the dashed line. It is noted that the arrangement of the magnets is not limited to that shown in FIGS. 3-7, and other configurations or combinations of the embodiments are similarly contemplated.

Although each embodiment includes a particular polarity arrangement of the magnets, the polarity arrangement is not required to be uniform or limited to the arrangement shown. For example, the magnets may have the same polarity orientation, have alternating polarity orientation, or include pattern or pattern-less polarity orientations along the dashed line.

In embodiments, electromagnets or electro-permanent magnets are magnets with windings that effectively yield the same result as the permanent magnet.

In various embodiments, the magnets are illustrated to be positioned along a ring; however, the ring shape is non-limiting, and other arrangements such as an octagon, square, oval, or the like that allow for symmetry are similarly contemplated.

In embodiments, the magnets are arranged at equal distances from the feed point or the ground point of antenna 102. In embodiments, due to an asymmetry of a field generated by antenna 102, the magnets may be selectively arranged (not necessarily at similar distances to the exterior or a central point) to correct for a skew in the generated plasma.

In embodiments, the magnets are arranged substantially on a ring outline with some minor (e.g., 5% inner or outer) positional misalignment in reference to the ring.

The arrangement of magnets along a ring is not limited to those disclosed solely with reference to FIGS. 3-7, and combinations of the embodiments are contemplated. For example, in embodiments, some magnets on the same ring are arranged as disclosed with two or more of arrangement of magnets 300, arrangement of magnets 400, arrangement of magnets 500, or a combination thereof. Some magnets on the ring may have an axis of polarity that is vertical while some magnets on the same ring may have an axis of polarity that is horizontal. As another example, some magnets on the ring may be arranged to have an axis that is radial to the ring while other magnets on the same ring are arranged to have an axis that is axial to the ring. Thus, any of the combinations disclosed above may be used as a configuration for the placement of magnets.

Each configuration, as disclosed hereinabove, may present a different effect on the plasma within the plasma chamber 106. For example, one configuration may improve the radial density profile across the plasma. As another example, one configuration may improve the azimuthal uniformity of the plasma. In embodiments, the position of the plane of the magnets is adjustable (e.g., mechanically or electrically) and can be shifted up and down based on the operation of the plasma processing system. In other embodiments, a plurality of electromagnets or electro-permanent magnets are arranged on different planes, and by turning on and off electromagnets or electro-permanent magnets on the different planes, a similar shifting of the magnetic field is envisioned.

In an embodiment, the magnets are arranged (or enabled in the case of an electromagnet or electro-permanent magnet) based on a real-time measurement of the plasma stability, electron temperature, plasma density, a change in plasma ignition stability, a change in the tunability of the matching network coupled to the antenna, or a combination thereof.

For example, the configuration of the magnets (e.g., polarity direction, location, strength, or the like) may be mechanically or electronically changed to improve plasma stability at low-pressure plasma conditions or the like.

In an embodiment, measurements from wafers between process steps can be used to adjust the magnetic field configuration for future wafers. In embodiments, the analysis includes measurements of the wafer thickness, feature height, trench depth, critical dimension (CD), uniformity, or a combination thereof.

In an embodiment, a feedback circuit is used to measure one or more parameters of the plasma processing system (i.e., plasma density, plasma impedance, etc.) and communicate the measurement to a controller circuit. The controller circuit can manually or automatically adjust the magnet configurations based on the received measurements.

In an embodiment, the magnets are arranged (or enabled in the case of an electromagnet or electro-permanent magnet) based on a pre-determined arrangement stored in a look-up table of a memory coupled to a controller used to adjust the configuration of the magnets.

For example, a first configuration of the magnets may be stored in the memory that is known to improve plasma stability at a first pressure; a second configuration of the magnets may be stored in the memory that is known to improve plasma stability at a second pressure; and so forth. Additional specific configurations may be stored in the memory for other parameters, combinations of parameters, or the like.

In embodiments, the controller electronically adjusts, for example, the location, strength, polarity, and the like of one or more magnets based on the pre-determined arrangement stored in the memory to improve one or more conditions that are principal to a particular plasma processing operation.

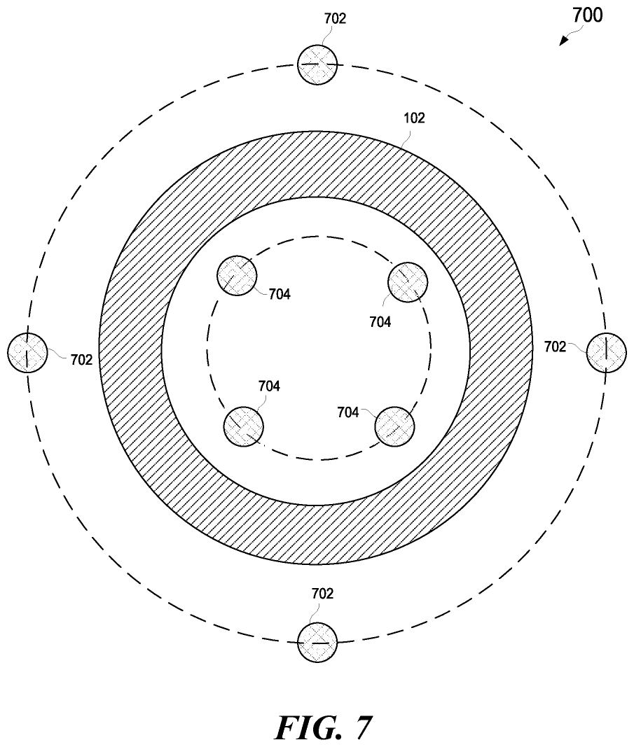

FIG. 8 illustrates a block diagram of an embodiment processing system 800, which may be coupled to the plasma processing system 100. As shown, the processing system 800 includes a processor 802, a memory 804, an interface 806, an optional feedback circuit 808, and an optional measurement circuit 810, which may (or may not) be arranged as shown. The processing system 800 may include additional components not depicted, such as long-term storage (e.g., non-volatile memory, etc.), measurement devices, and the like.

Processor 802 may be any component or collection of components adapted to perform computations or other processing related tasks. Memory 804 may be any component or collection of components adapted to store programming or instructions for execution by the processor 802. In an embodiment, the memory 804 includes a non-transitory computer readable medium.

Interface 806 may be any component or collection of components that allow the processor 802 to communicate with other devices/components or a user. For example, interface 806 may be adapted to communicate data, control, or management messages from processor 802 to a structure or circuit coupled to the one or magnets to adjust the configuration of the magnets based on instructions or configurations stored in memory 804.

As another example, interface 806 may be adapted to allow a user or device (e.g., personal computer (PC), etc.) to interact/communicate with the processing system 800.

Feedback circuit 808 may be used to receive measurements from the measurement circuit 810 to automatically or manually change, through processor 802, the configuration of magnets in the plasma processing system 100. The measurement circuit 810 may be used to measure, for example, the plasma stability, pressure, ignition stability, density, or the like.

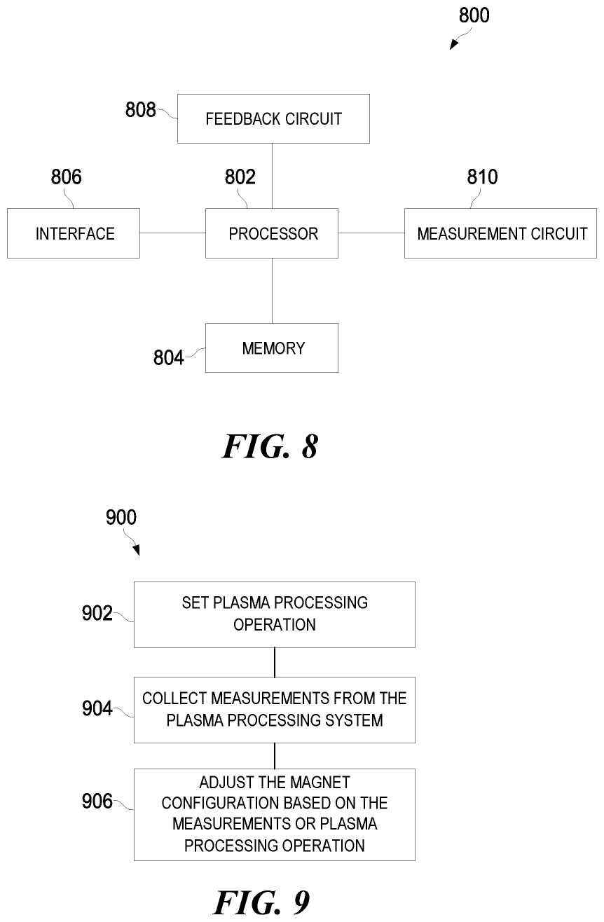

FIG. 9 is a flow chart of an embodiment method 900 to adjust the magnet configuration of the plasma processing system 100. At step 902, the plasma processing operation is set. The plasma processing operation corresponds to an operation such as etching, deposit, oxidation, sputtering, or the like. The plasma processing operation sets the, for example, pressure condition, frequency, and the like, for processing a wafer in the plasma processing system.

Optionally, at step 904, various parameters associated with the plasma processing system are collected using, for example, the measurement circuit 810. For example, the measurement circuit may be configured to collect the plasma density, stability, ignition stability, pressure, or the like.

At step 906, the plasma processing system 100 using, for example, processor 802 adjusts the magnet configuration. Processor 802 may adjust the magnet configuration based on the plasma processing operation, the collected measurements, or a combination thereof.

In embodiments, processor 802 may select the magnet configuration based on a look-up table stored in, for example, memory 804. The look-up table may be used to indicate or instruct the processor to reconfigure the magnets to achieve a specific value(s) for the parameter(s) associated with the plasma processing system. For example, processor 802 may adjust the magnet configurations to achieve a specific plasma density or stability as specified within the look-up table. In embodiments, processor 802 may communicate with the feedback circuit 808 and the measurement circuit 81o to further refine the magnet configuration.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure. It should be appreciated that the physical arrangement and disposition of the components in the various embodiments of, for example, the plasma processing system or the resonating structures are non-limiting. For example, although the resonating structure is arranged between the RF source and the plasma processing system in the various illustrations, this arrangement is non-limiting, and these components may be arranged adjacent, above, or below the other components while within the scope of the present disclosure.

What is claimed is:

1. A plasma processing system, comprising:
a plasma chamber;
a planar antenna configured to generate plasma within the plasma chamber;
a dielectric plate disposed between the plasma chamber and the planar antenna; and
a plurality of magnets arranged vertically above an outer surface of the dielectric plate that faces the plasma chamber.

2. The plasma processing system of claim 1, wherein one or more magnets of the plurality of magnets are a permanent magnet, an electromagnet, an electro-permanent magnet (EPM), or a combination thereof.

3. The plasma processing system of claim 1, wherein one or more magnets of the plurality of magnets have an axis of polarity perpendicular to the dielectric plate, parallel to the dielectric plate, or a combination thereof.

4. The plasma processing system of claim 1, wherein one or more magnets of the plurality of magnets are arranged along a ring parallel to the planar antenna, and wherein one or more magnets of the plurality of magnets have an axis of polarity perpendicular to the ring, tangent to the ring, or a combination thereof.

5. The plasma processing system of claim 1, further comprising a housing structure, the antenna arranged within the housing structure, and the dielectric plate positioned between the housing structure and the plasma chamber.

6. The plasma processing system of claim 5, wherein one or more magnets of the plurality of magnets are arranged external to the housing structure.

7. The plasma processing system of claim 1, wherein one or more magnets of the plurality of magnets are arranged on a plane parallel to the planar antenna.

8. The plasma processing system of claim 7, wherein the plane is adjustable in a vertical direction from the outer surface of the dielectric plate that faces the plasma chamber to a second plane, wherein the planar antenna is arranged between the second plane and the dielectric plate.

9. A plasma processing system, comprising:
a plasma chamber having a top side and a bottom side opposing the top side;
an antenna configured to generate plasma in a plasma generating region within the plasma chamber;
a dielectric plate arranged between the plasma chamber and the antenna, an uppermost surface of the plasma generating region being a surface corresponding to the bottom side of the dielectric plate adjacent to the top side of the plasma chamber; and
a plurality of magnets arranged vertically above the uppermost surface of the plasma generating region in a direction from bottom side of the plasma chamber towards the top side of the plasma chamber, wherein a position or an axis of polarity of one or more of the plurality of magnets is configurable.

10. The plasma processing system of claim 9, wherein one or more magnets of the plurality of magnets are a permanent magnet, an electromagnet, an electro-permanent magnet (EPM), or a combination thereof.

11. The plasma processing system of claim 9, wherein one or more magnets of the plurality of magnets have an axis of polarity perpendicular to the plasma, parallel to the plasma, or a combination thereof.

12. The plasma processing system of claim 9, wherein the antenna is in a shape of a donut, wherein a first subset of magnets is arranged on a first plane at an outer circumference of the antenna and parallel to the antenna, and wherein a second subset of magnets is arranged on a second plane within an inner circumference of the antenna and parallel to the antenna.

13. The plasma processing system of claim 12, wherein the first plane and the second plane are the same plane.

14. The plasma processing system of claim 12, wherein the magnets of the first subset of magnets are arranged symmetrically around the outer circumference of the antenna, and wherein the magnets of the second subset of magnets are arranged symmetrically within the inner circumference of the antenna.

15. The plasma processing system of claim 9, wherein a determination of an arrangement of the magnets is based on a change in density, stability, pressure, ignition stability of the plasma, change in tunability of a matching network coupled to the antenna, or a combination thereof.

16. The plasma processing system of claim 9, wherein the plasma is a low-pressure plasma corresponding to a pressure of 10 millitorr (mTorr) or less.

17. A method of operating a plasma processing system, the method comprising:
setting a plasma processing operation for the plasma processing system, wherein the plasma processing system comprises:
a plasma chamber,
an antenna used to generate plasma within the plasma chamber,
a dielectric plate arranged between the plasma chamber and the antenna, and
a plurality of magnets arranged vertically above an outer surface of the dielectric plate that faces the plasma chamber;
measuring one or more parameters associated with the plasma processing system; and
adjusting a placement of one or more magnets based on the plasma processing operation and the one or more parameters.

18. The method of claim 17, wherein the one or more parameters comprises one or more of plasma stability, electron temperature, plasma ignition stability, plasma density, or tunability of a matching network coupled to the antenna.

19. The method of claim 17, wherein one or more magnets of the plurality of magnets are stationary electromagnets, and wherein adjusting the placement of one or more magnets comprises enabling, disabling, adjusting, or reversing a current in one or more of the stationary electromagnets.

20. The method of claim 17, wherein one or more magnets of the plurality of magnets are permanent magnets arranged on a mechanical structure parallel to the outer surface of the dielectric plate, and wherein adjusting the placement of one or more magnets comprises vertically shifting the mechanical structure between a first plane and a second plane, the first plane being the outer surface of the dielectric plate, the second plane being a plane vertically above the antenna.

21. The method of claim 17, wherein the adjusting comprises determining a configuration of magnets using a look-up table, the look-up table having a plurality of configurations for the magnets based on the plasma processing operation and the one or more parameters.
